(19) United States
(12) Patent Application Publication
(10) Pub. No.: US 2013/0277636 A1
(43) Pub. Date: Oct. 24, 2013

(54) VARIABLE RESISTANCE MEMORY DEVICE AND METHOD FOR FABRICATING THE SAME

(71) Applicants: Kee-Jeung Lee, Gyeonggi-do (KR); Woo-Young Park, Gyeonggi-do (KR)

(72) Inventors: Kee-Jeung Lee, Gyeonggi-do (KR); Woo-Young Park, Gyeonggi-do (KR)

(21) Appl. No.: 13/596,637

(22) Filed: Aug. 28, 2012

(30) Foreign Application Priority Data
Apr. 19, 2012 (JP) 10-2012-0041005

(51) Int. Cl. H01L 21/02; H01L 47/00

(52) U.S. Cl. 257/2; 438/104; 257/E47.001; 257/E21.004

(57) ABSTRACT

A method for fabricating a variable resistance memory device includes forming a first electrode, forming a first metal oxide layer which satisfies chemical stoichiometry over the first electrode, forming a second metal oxide layer which is lower in oxygen content than the first metal oxide layer by reducing a part of the first metal oxide layer, and forming a second electrode over the second metal oxide layer.

### CROSS-REFERENCE TO RELATED APPLICATIONS

The present application claims priority of Korean Patent Application No. 10-2012-0041005, filed on Apr. 19, 2012, which is incorporated herein by reference in its entirety.

### BACKGROUND

1. Field

Exemplary embodiments of the present invention relate to a semiconductor technology, and more particularly, to a variable resistance memory device and a method for fabricating the same.

2. Description of the Related Art

Diverse variable resistance memory devices which store data using a material in different resistance states depending on applied biases (hereinafter, referred to as a ‘variable resistance material’ have been developed.

Among various variable resistance memory devices, a device switching between two states by filaments as a kind of current paths locally created and destroyed in a variable resistance material layer mainly formed of a metal oxide is called an ReRAM (resistive random access memory). Because creation and destruction of the filaments occur due to migration of oxygen vacancies in the metal oxide, a metal oxide deficient in oxygen to achieve chemical stoichiometry is to be used as a variable resistance material.

Meanwhile, as the degree of integration in a semiconductor device increases, various three-dimensional structures in which memory cells are stacked one another on a substrate have been developed. In such a trend, variable resistance memory devices are being developed to have three-dimensional structures. In order to fabricate a variable resistance memory device with a three-dimensional structure, atomic layer deposition (ALD) or chemical vapor deposition (CVD) with excellent step coverage characteristics may be used when depositing a variable resistance material layer.

However, when using ALD or CVD as described above, it is difficult to form a metal oxide layer deficient in oxygen to achieve the chemical stoichiometry, as a variable resistance material.

In detail, in ALD or CVD, a metal oxide layer is formed by reacting a metal organic precursor with oxygen. At this time, in order to reduce an oxygen content of the metal oxide layer, a supply amount of oxygen as a reactant gas is to be decreased. In this case, since the ligand of the metal organic precursor is not sufficiently dissolved, impurities of carbon or hydrogen are likely to remain in the metal oxide layer and accordingly, the characteristics of the metal oxide layer may be degraded. Nevertheless, if a supply amount of oxygen as a reactant gas is sufficiently increased, because a metal oxide layer satisfying the chemical stoichiometry is formed, a variable resistance material layer may not be formed.

### SUMMARY

Exemplary embodiments of the present invention are directed to a variable resistance memory device which has excellent switching characteristics while having a three-dimensional structure, through improvement of processes, and a method for fabricating the same.

In accordance with an exemplary embodiment of the present invention, a method for fabricating a variable resistance memory device includes forming a first electrode, forming a first metal oxide layer which satisfies chemical stoichiometry over the first electrode, forming a second metal oxide layer which is lower in oxygen content than the first metal oxide layer by reducing a part of the first metal oxide layer, and forming a second electrode over the second metal oxide layer.

In accordance with another exemplary embodiment of the present invention, a method for fabricating a variable resistance memory device includes alternately stacking a plurality of first material layers and a plurality of interlayer dielectric layers over a substrate; forming a hole which exposes sidewalls of the plurality of first material layers by selectively etching the alternately stacked structure, forming a first metal oxide layer which satisfies chemical stoichiometry in the hole, forming a second metal oxide layer which is lower in oxygen content than the first metal oxide layer by reducing a part of the first metal oxide layer, and forming a second electrode in the hole in which the second metal oxide layer is formed.

In accordance with yet another exemplary embodiment of the present invention, a variable resistance memory device includes a bottom electrode, a variable resistance material layer including a first metal oxide layer and a second metal oxide layer which are sequentially stacked over the bottom electrode, wherein the first metal oxide satisfies chemical stoichiometry, and the second metal oxide layer is lower in oxygen content than the first metal oxide layer while having the same material as the first metal oxide layer, and a top electrode formed over the variable resistance material layer.

### BRIEF DESCRIPTION OF THE DRAWINGS

FIGS. 1A to 1C are cross-sectional views illustrating a unit cell of a variable resistance memory device and a method for fabricating the same in accordance with exemplary embodiments of the present invention.

FIG. 2 is a graph exemplarily showing a change of a metal oxide layer depending on plasma processing shown in FIG. 1B.

FIG. 3A is a graph exemplarily showing switching characteristics of the unit cell shown in FIG. 1C, and FIG. 3B is a graph exemplarily showing switching characteristics of another unit cell, for comparison with FIG. 3A.

FIGS. 4A to 6B are views illustrating a variable resistance memory device and a method for fabricating the same in accordance with other embodiments of the present invention.

FIG. 7 is a view illustrating a variable resistance memory device and a method for fabricating the same in accordance with still other exemplary embodiments of the present invention.

FIG. 8 is a cross-sectional view showing a unit cell of a variable resistance memory device in accordance with other exemplary embodiments of the present invention.

FIG. 9 is a cross-sectional view showing a unit cell of a variable resistance memory device in accordance with still other exemplary embodiments of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

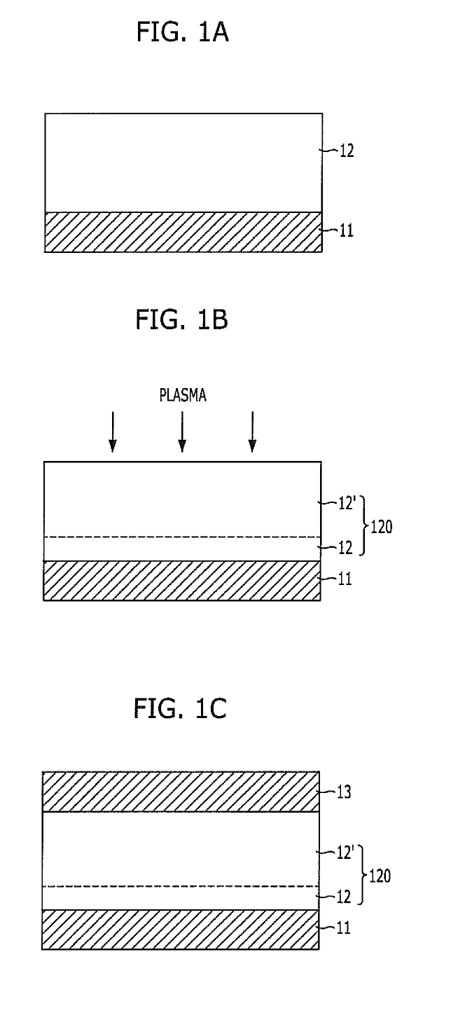

FIGS. 1A to 1C are cross-sectional views illustrating a unit cell of a variable resistance memory device and a method for fabricating the same in accordance with exemplary embodiments of the present invention. In particular, FIG. 1C shows a fabricated unit cell, and FIGS. 1A and 1B show intermediate processing steps for fabricating the unit cell shown in FIG. 1C.

Referring to FIG. 1A, a first electrode 11 is formed on a substrate (not shown) including a given underlying structure. The first electrode 11 is to apply a voltage to a variable resistance material layer in cooperation with a second electrode which will be described below. The first electrode 11 may include a conductive material such as a metal, for example, platinum (Pt), tungsten (W), aluminum (Al), copper (Cu) and tantalum (Ta), and a metal nitride, for example, a titanium nitride (TiN) and a tantalum nitride (TaN).

Then, a first metal oxide layer 12 is formed on the first electrode 11, as a variable resistance material. The first metal oxide layer 12 may include, for example, a Ti oxide, a Ta oxide, an Fe oxide, a W oxide, an Hf oxide, an Nb oxide and a Zr oxide.

In the embodiment of the present invention, the first metal oxide layer 12 may be formed through ALD in which a cycle constituted by implantation of a metal organic precursor, purge, implantation of a reactant gas including oxygen and purge is repeated. Otherwise, the first metal oxide layer 12 may be formed through CVD in which a metal organic precursor and a reactant gas including oxygen are implanted together. In particular, in the embodiment of the present invention, when forming the first metal oxide layer 12 through ALD or CVD, the reactant gas including oxygen is sufficiently implanted such that the ligand of the metal organic precursor may be actively dissolved to prevent impurities of carbon or hydrogen from remaining in the first metal oxide layer 12. In this case, as the characteristics of the first metal oxide layer 12 are improved, a material satisfying chemical stoichiometry is obtained. For example, the first metal oxide layer 12 is constituted by, in particular, Ta₂O₅ satisfying the chemical stoichiometry, among Ta oxides.

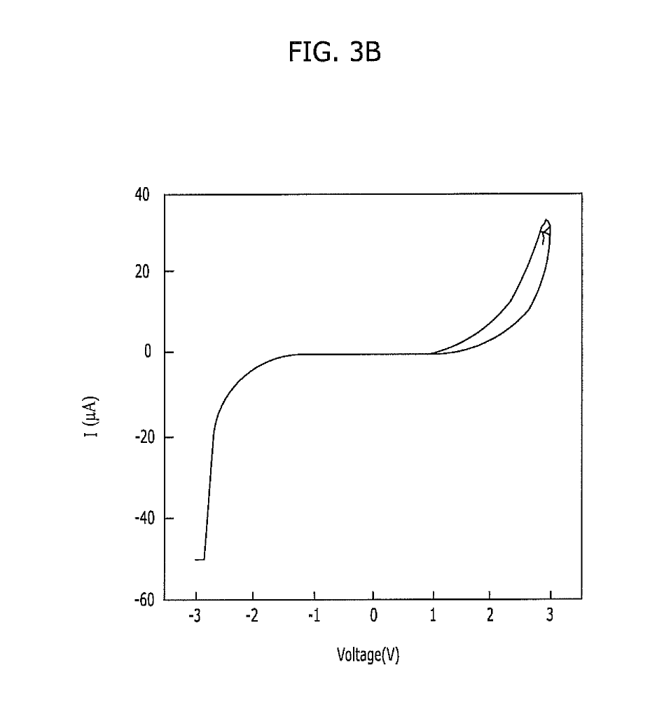

However, when the first metal oxide layer 12 is a material satisfying the chemical stoichiometry, since the first metal oxide layer 12 does not include oxygen vacancies, switching characteristics by creation and destruction of filaments may not be achieved. It may be readily seen from FIG. 3 which will be described later. Thus, a subsequent process of FIG. 1B is performed.

Referring to FIG. 1B, plasma processing is performed for the first metal oxide layer 12 under an atmosphere of a reduction gas. The reduction gas may be, for example, a hydrogen-containing gas such as H₂ and NH₃. Also, the plasma processing may be performed under an atmosphere further including an inert gas, for example, such as argon (Ar), in addition to the reduction gas.

When performing such plasma processing, as bonds between a metal and oxygen are broken, oxygen ions are dissociated from the surface of the first metal oxide layer 12, and oxygen vacancies are produced in those positions. As a consequence, at least a part of the first metal oxide layer 12 is reduced from the surface thereof and changed to a second metal oxide layer 12′ which is lower in oxygen content than the first metal oxide layer 12. For example, in the case where the first metal oxide layer 12 is constituted by Ta₂O₅, the second metal oxide layer 12′ may be constituted by TaOx (x is less than 2.5).

Since the thickness of the second metal oxide layer 12′ increases in proportion to a plasma processing time, the thickness of the second metal oxide layer 12′ may be easily controlled by controlling the plasma processing time. In the embodiment of the present invention, the plasma processing time may be controlled such that the first metal oxide layer 12 is not completely reduced and partially remains and the thickness of the second metal oxide layer 12′ is equal to or larger than the thickness of the first metal oxide layer 12 remaining after the plasma processing. Advantages obtained in this case will be described later.

As a result of this process, a variable resistance material layer 120 with a stack structure of the first metal oxide layer 12 satisfying the chemical stoichiometry and the second metal oxide layer 12′ deficient in oxygen to achieve the chemical stoichiometry is formed on the first electrode 11.

Referring to FIG. 1C, a second electrode 13 is formed on the variable resistance material layer 120. As described above, the second electrode 13 is to apply a voltage to the variable resistance material layer 120 in cooperation with the first electrode 11. The second electrode 13 may include a conductive material such as a metal, for example, platinum (Pt), tungsten (W), aluminum (Al), copper (Cu) and tantalum (Ta), and a metal nitride, for example, a titanium nitride (TiN) and a tantalum nitride (TaN).

By the above-described processes, a unit cell as shown in FIG. 1C is formed.

Referring again to FIG. 1C, the unit cell of a variable resistance memory device in accordance with the embodiment of the present invention includes the first electrode 11, the second electrode 13, and the variable resistance material layer 120 interposed therebetween.

The variable resistance material layer 120 has the stack structure of the first metal oxide layer 12 satisfying the chemical stoichiometry and the second metal oxide layer 12′ deficient in oxygen to achieve the chemical stoichiometry. Because the second metal oxide layer 12′ includes oxygen vacancies, it has variable resistance characteristics for switching between a low resistance state and a high resistance state as filaments are created and destroyed in the second metal oxide layer 12′. The first metal oxide layer 12 as a dielectric material serves as a tunneling barrier against electrons.

As the thickness of the second metal oxide layer 12′ is larger than the first metal oxide layer 12, the switching characteristics are improved and an operation voltage may be decreased. However, if the relative thickness of the second metal oxide layer 12′ excessively increases such that the first metal oxide layer 12 does not exist or becomes too thin to serve as the tunneling barrier, leakage current may be produced in a structure in which a plurality of cells share electrodes such as a cross point structure to be described later. Therefore, advantageously, the second metal oxide layer 12′ may have a thickness equal to or larger than the first metal oxide layer 12, and at the same time, the first metal oxide layer 12 may remain to have a given thickness to serve as the tunneling barrier against electrons. For example, the thickness ratio between the first metal oxide layer 12 and the second metal oxide layer 12′ may have a range of 1:1 to 1:3.

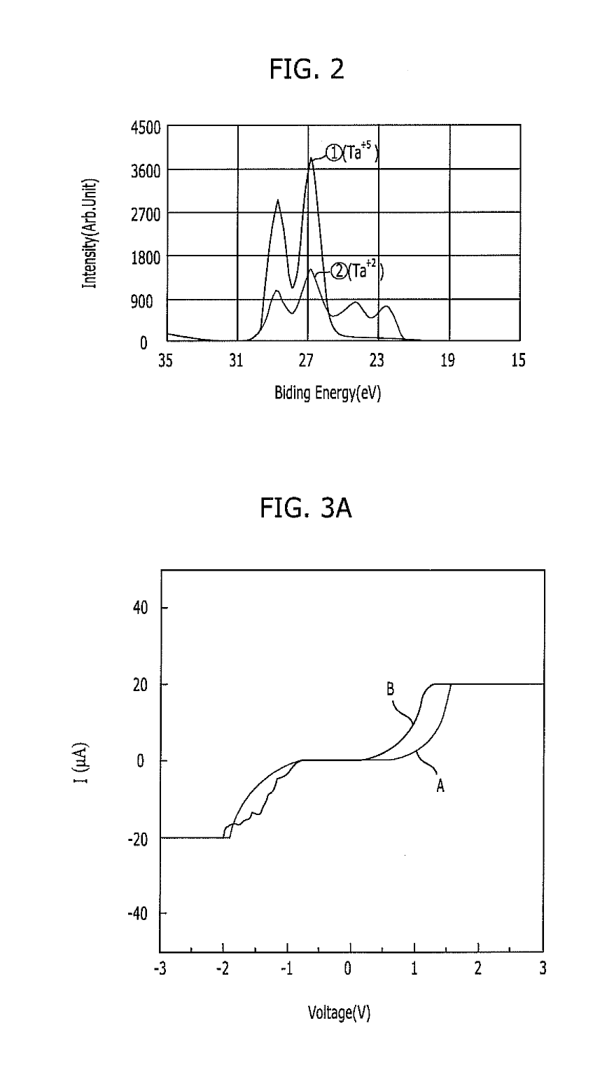

FIG. 2 is a graph exemplarily showing a change of a metal oxide layer depending on plasma processing of FIG. 1B. FIG. 2 shows results of an XPS (X-ray photoelectron microscopy) analysis after a Ta₂O₅ layer is deposited on a TiN electrode through ALD and plasma processing is performed under an H₂ gas atmosphere.

Referring to FIG. 2, a Ta⁵⁺ constituent is prominent in the case where plasma processing is performed for 200 seconds under an atmosphere of an H₂ gas (see \textcircled{1}), and a Ta²⁺ constituent is prominent in the case where plasma processing is performed for 1000 seconds under the atmosphere of the H₂ gas (see \textcircled{2}). In other words, as a plasma processing time is lengthened under the atmosphere of the H₂ gas, the degree of reduction increases and the Ta₂O₅ layer is changed into the TaOx (x is less than 2.5) layer.

FIG. 3A is a graph exemplarily showing switching characteristics of the unit cell of FIG. 1C, and FIG. 3B is a graph exemplarily showing switching characteristics of another unit cell, for comparison with FIG. 3A. In detail, FIG. 3A shows current-voltage characteristics measured in a unit cell including the stack structure of two TiN electrodes, and a Ta₂O₅ layer with a thickness of about 5 Å and a TaOx layer (x<2.5) with a thickness of about 15 Å which are interposed between the two TIN electrodes. FIG. 3B shows current-voltage characteristics measured in a unit cell including two TiN electrodes and a Ta₂O₅ layer with a thickness of about 20 Å which is interposed between the two TIN electrodes. That is to say, FIG. 3B shows the characteristics of the unit cell in the case where the plasma processing according to the embodiment of the present invention is omitted.

Referring to FIG. 3A, the unit cell of FIG. 1C operates in a bipolar mode in which a set operation (see A) for changing from a high resistance state to a low resistance state and a reset operation (see B) for changing from the low resistance state to the high resistance state occur at different polarities, and in particular, the set and reset operations occur substantially symmetrically. Accordingly, uniform switching characteristics may be secured. In addition, an operation voltage is within a range of about −2 to 2V and an operation current is within a range of about −20 to 20 μA. Namely, the operation voltage and the operation current are relatively small.

On the contrary, referring to FIG. 3B, set and reset operations asymmetrically occur in the case of a unit cell which uses a Ta₂O₅ layer as a variable resistance material layer. This is because resistance states are changed not as filaments are created and destroyed in the Ta₂O₅ layer but as charges are trapped and detrapped on the interface of the Ta₂O₅ layer. Accordingly, uniform switching characteristics may not be secured. In addition, an operation voltage and an operation current increase when compared to FIG. 3A.

As a result, in the case where a metal oxide layer satisfying chemical stoichiometry is partially changed into a metal oxide layer deficient in oxygen to achieve the chemical stoichiometry, by performing plasma processing as described in the above embodiment, advantages are provided in terms of securing switching characteristics and decreasing an operation voltage and an operation current.

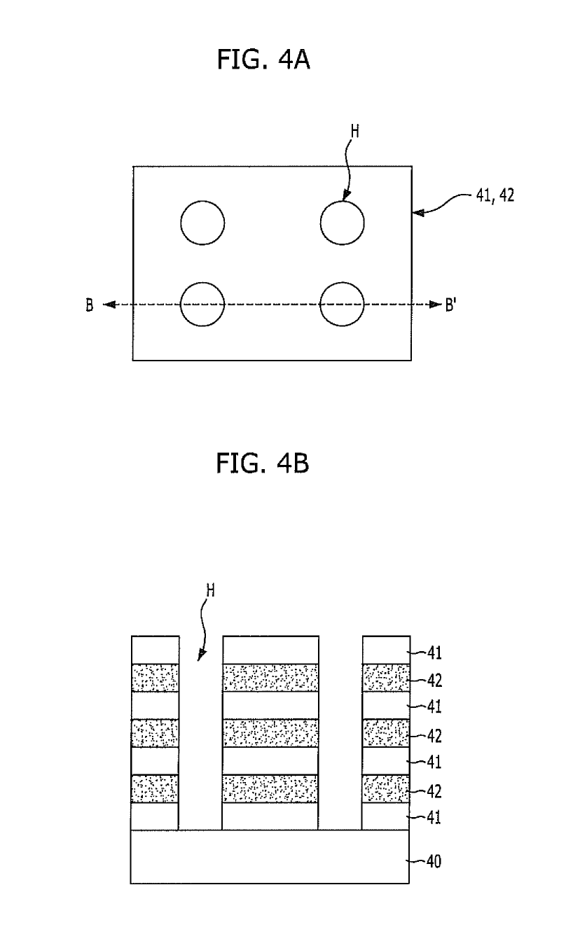

FIGS. 4A and 4B to 6A and 6B are views illustrating a variable resistance memory device and a method for fabricating the same in accordance with other embodiments of the present invention. FIGS. 4A to 6A are plan views, and FIGS. 4B to 6B are cross-sectional views taken along the lines B-B′ of FIGS. 4A to 6A, respectively. The variable resistance memory device according to the embodiment of the present invention includes a plurality of unit cells each of which is as shown in FIG. 1C, and in particular, it has a three-dimensional structure in which unit cells are stacked on a substrate one another.

Referring to FIGS. 4A and 4B, a plurality of interlayer dielectric layers 41 and a plurality of sacrificial layers 42 are alternately stacked on a substrate 40 having a given underlying structure.

The plurality of sacrificial layers 42 are to be replaced with horizontal electrodes in a subsequent process and may include layers having an etching selectivity with respect to the interlayer dielectric layers 41, for example, nitride layers. The interlayer dielectric layers 41 are to isolate a plurality of layers of horizontal electrodes from one another and may include, for example, an oxide layer.

Then, by selectively etching the alternate stack structure of the interlayer dielectric layers 41 and the sacrificial layers 42, holes H for exposing the substrate 40 are formed. The holes H define regions where a variable resistance material layer and vertical electrodes are to be formed as described below.

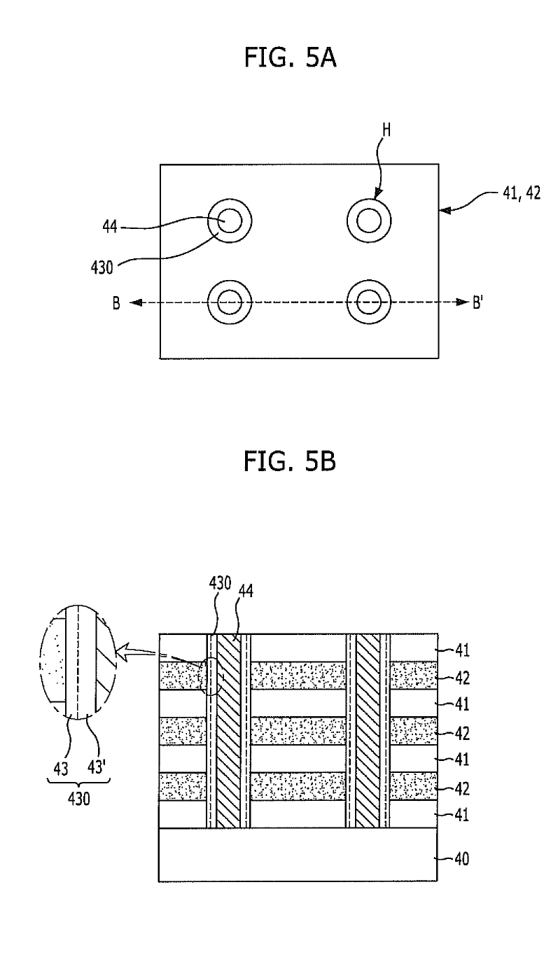

Referring to FIGS. 5A and 5B, a variable resistance material layer 430 is formed on the sidewalls of the holes H. A method for forming the variable resistance material layer 430 is substantially the same as the method for forming the variable resistance material layer 120 as shown in FIGS. 1A to 1C.

In detail, a first metal oxide layer 43 is formed on the entire surface of the resultant structure including the holes H. Since the aspect ratio of the holes H is relatively large, the first metal oxide layer 43 is formed through ALD or CVD. Accordingly, the first metal oxide layer 43 is formed to satisfy chemical stoichiometry. Next, by performing plasma processing for the first metal oxide layer 43 under an atmosphere of a reduction gas, the first metal oxide layer 43 is reduced at least partially from the surface thereof, and the first metal oxide layer 43 is changed to a second metal oxide layer 43′. The second metal oxide layer 43′ lacks oxygen when compared to the first metal oxide layer 43. In succession, by performing blanket etching, the variable resistance material layer 430 remains only on the sidewalls of the holes H.

In this way, as ALD or CVD is used when forming the variable resistance material layer 430, step coverage characteristics for a three-dimensional structure may be satisfied. Also, when performing ALD or CVD, a reactant gas including oxygen is sufficiently supplied such that the layer characteristics of the variable resistance material layer 430 may be improved, and the switching characteristics of a variable resistance memory device may be improved since the variable resistance material layer 430 may be formed to partially include oxygen vacancies through a reduction process using the plasma processing.

Thereafter, by filling a conductive material in the holes H, vertical electrodes 44 which extend vertically from the substrate 40 are formed. The vertical electrodes 44 correspond to any one of the first and second electrodes 11 and 13 of FIGS. 1A to 1C.

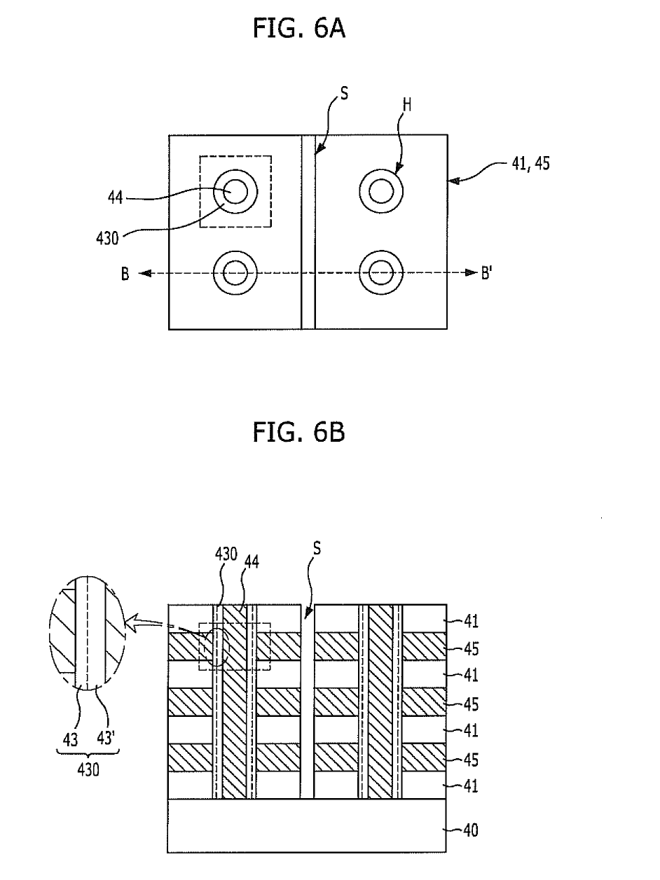

Referring to FIGS. 6A and 6B, by selectively etching the alternate stack structure of the interlayer dielectric layers 41 and the sacrificial layers 42, slits S are defined at least by such a depth as to pass through the plurality of sacrificial layers 42. The slits S are to provide spaces into which a wet etching solution for removing the sacrificial layers 42 penetrates. While the slits S are defined to extend in a direction crossing with the B-B direction in the embodiment of the present invention, it is to be noted that the present invention is not limited to such.

Then, after removing the sacrificial layers 42 exposed through the slits S using wet etching, etc., horizontal electrodes 45 which are disposed parallel to the substrate 40 are formed by filling a conductive material in the spaces from which the sacrificial layers 42 are removed. The horizontal electrodes 45 correspond to the other of the first and second electrodes 11 and 13 of FIGS. 1A to 1C.

By the above-described processes, the variable resistance memory device as shown in FIGS. 6A and 6B is fabricated. In the variable resistance memory device, one vertical electrode 44, one horizontal electrode 45 surrounding the one vertical electrode 44 and the variable resistance material layer 430 interposed therebetween constitute a unit cell. When a unit cell indicated by the dotted line is selected, leakage current may occur to another cell sharing the horizontal electrode 45 with the selected cell or another cell sharing the vertical electrode 44 with the selected cell. However, since the first metal oxide layer 43 of the variable resistance material layer 430 serves as a tunneling barrier against electrons, migration of electrons under a low voltage is suppressed to prevent the occurrence of leakage current.

While not shown, the processes shown in FIGS. 4A to 6B may be modified as follows. That is to say, in the process of FIGS. 4A and 4B, a conductive layer for horizontal electrodes may be directly deposited instead of the sacrificial layers 42. In this case, the process for replacing the sacrificial layers 42 with the horizontal electrodes 45 as shown in FIGS. 6A and 6B may be omitted.

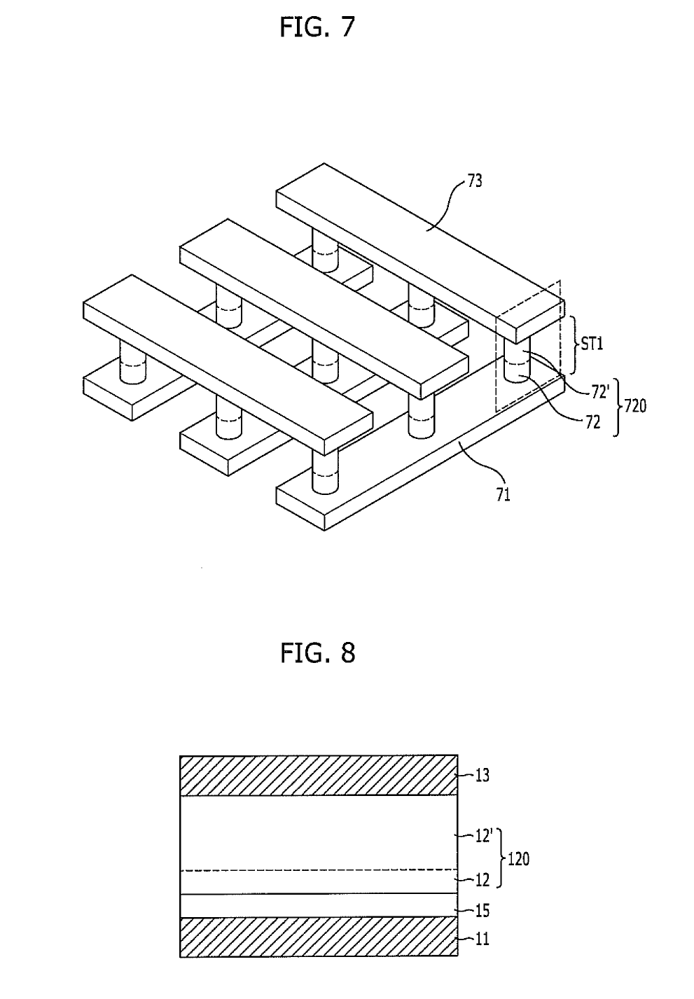

FIG. 7 is a view illustrating a variable resistance memory device and a method for fabricating the same in accordance with still other embodiments of the present invention. The variable resistance memory device according to the embodiment of the present invention has a structure in which a plurality of unit cells each as shown in FIG. 1C are disposed at crossing points of electrodes.

Referring to FIG. 7, by depositing and patterning a conductive material on a substrate (not shown) having a given underlying structure, a plurality of first electrodes 71 which are parallel to one another and extend in one direction are formed. A dielectric material may be filled between the first electrodes 71.

Next, a variable resistance material layer 720 is formed on the first electrodes 71. A method for forming the variable resistance material layer 720 is substantially the same as the method for forming the variable resistance material layer 120 as shown in FIGS. 1A to 1C.

In detail, a first metal oxide layer 72 is formed on the resultant structure including the first electrodes 71. The first metal oxide layer 72 is formed through ALD or CVD to satisfy chemical stoichiometry. Then, by performing plasma processing for the first metal oxide layer 72 under an atmosphere of a reduction gas, the first metal oxide layer 72 is reduced at least partially from the surface thereof, and the first metal oxide layer 72 is changed to a second metal oxide layer 72′. In succession, by performing patterning, the variable resistance material layer 720 is formed at each position where second electrodes 73 and the first electrodes 71 cross each other. Thereafter, a dielectric material is filled between portions of the variable resistance material layer 720. While the shapes of the variable resistance material layer 720 are defined through patterning in the embodiment of the present invention, it is to be noted that the present invention is not limited to such. In another embodiment, the variable resistance material layer 720 may be formed in such a manner that, after forming a dielectric material to cover the first electrodes 71 and defining holes in the dielectric material in which the variable resistance material layer 720 may be filled, the first metal oxide layer 72 is deposited in the holes and plasma processing is performed.

After a conductive material is deposited on the variable resistance material layer 720 and a dielectric material filling the spaces therebetween, a plurality of second electrodes 73, which are parallel to one another and extend in a direction crossing with the first electrodes 71, are formed by patterning the deposited conductive material.

By the above-described processes, the variable resistance memory device as shown in FIG. 7 is fabricated. In the variable resistance memory device, a unit cell is formed at each crossing point of the first electrodes 71 and the second electrodes 73. When a unit cell indicated by the dotted line is selected, leakage current may occur to another cell sharing the first electrode 71 with the selected cell or another cell sharing the second electrode 73 with the selected cell. However, since the first metal oxide layer 72 of the variable resistance material layer 720 serves as a tunneling barrier against electrons, migration of electrons under a low voltage is suppressed to prevent the occurrence of leakage current.

It was explained in the aforementioned embodiments that the first metal oxide layer satisfying chemical stoichiometry serves as a tunneling barrier. In addition, when a layer serving as a tunneling barrier is interposed between the first metal oxide layer and the electrodes and/or between the second metal oxide layer and the electrodes, leakage current may be further reduced. Hereinbelow, this will be described in detail with reference to FIG. 8.

FIG. 8 is a cross-sectional view showing a variation of the unit cell of FIG. 1C.

Referring to FIG. 8, a tunneling barrier 15 is additionally interposed between a first electrode 11 and a first metal oxide layer 12. The tunneling barrier 15 may be formed of a material which has an energy band gap larger than the first metal oxide layer 12, and accordingly, an operation current may be entirely reduced. If the operation current is reduced, since current flowing under a low voltage is reduced, leakage current may be further reduced.

The tunneling barrier 15 may be formed of any material so long as the material has an energy band gap larger than the first metal oxide layer 12. For example, in the case where the first metal oxide layer 12 is formed of Ta₂O₅ having an energy band gap of about 4.7 eV, a single layer or a multi-layer including Si₃N₅, SiO₂, Al₂O₃, SiON and an Si-rich dielectric layer such as SRO (Si-rich oxide) may be used.

While not shown in the drawing, the tunneling barrier 15 may be interposed between a second metal oxide layer 12′ and a second electrode 13.

The unit cell of the above embodiment may of course be applied to the variable resistance memory devices according to the aforementioned embodiments.

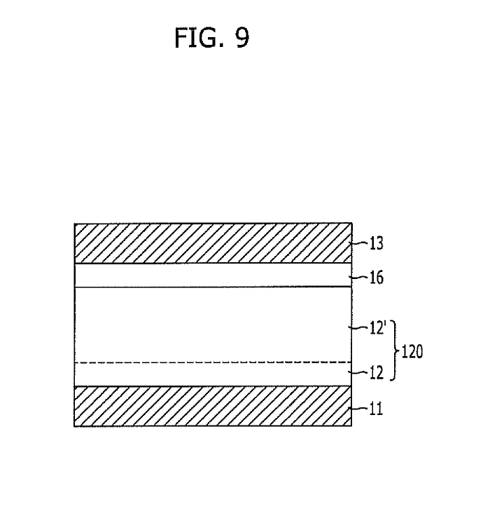

It was explained in the aforementioned embodiments that the second metal oxide layer 12′ which does not satisfy the chemical stoichiometry includes oxygen vacancies so that filaments may be created and destroyed. In addition, a third metal oxide layer may be interposed between the second metal oxide layer 12′ and the electrode to serve as an oxygen reservoir for supplying oxygen vacancies to the second metal oxide layer 12′. Hereinbelow, this will be described in detail with reference to FIG. 9.

FIG. 9 is a cross-sectional view showing another variation of the unit cell of FIG. 1C.

Referring to FIG. 9, a third metal oxide layer 16 is interposed between the second electrode 13 and the second metal oxide layer 12′. The third metal oxide layer 16 is to supply oxygen vacancies to the second metal oxide layer 12′, and it may include, for example, a TiOx (1.5<x<2.0) layer or a TaOx (1.5<x<2.5) layer. Further, while not shown, the upper portion of the third metal oxide layer 16 may be reduced by performing plasma processing under an atmosphere of a reduction gas after forming the third metal oxide layer 16.

Moreover, the unit cell of the above embodiment may of course be applied to the variable resistance memory devices according to the aforementioned embodiments.

As apparent from the above descriptions, in the variable resistance memory device and the method for fabricating the same according to the embodiments of the present invention, excellent switching characteristics may be obtained while having a three-dimensional structure, through improvement of processes.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a variable resistance memory device, comprising:
forming a first electrode;
forming a first metal oxide layer which satisfies chemical stoichiometry, over the first electrode;
forming a second metal oxide layer which is lower in oxygen content than the first metal oxide layer by reducing a part of the first metal oxide layer; and
forming a second electrode over the second metal oxide layer.

2. The method of claim 1, wherein the forming of the first metal oxide layer is performed through an atomic layer deposition (ALD) or a chemical vapor deposition (CVD).

3. The method of claim 1, wherein the forming of the second metal oxide layer is performed using plasma processing under an atmosphere of a reduction gas.

4. The method of claim 3, wherein the reduction gas include at least one of H₂ and NH₃.

5. The method of claim 1, wherein the first metal oxide layer includes Ta₂O₅, and the second metal oxide layer includes TaOx, x being less than 2.5.

6. The method of claim 1, wherein the second metal oxide layer has a thickness larger than the first metal oxide layer.

7. The method of claim 3, wherein relative thicknesses of the first metal oxide layer and the second metal oxide layer are controlled by adjusting a time of the plasma processing.

8. The method of claim 1, further comprising:
forming a material layer having an energy band gap larger than the first metal oxide layer, over the first electrode, before the forming of the first metal oxide layer.

9. The method of claim 1, further comprising:
forming a material layer having an energy band gap larger than the first metal oxide layer, over the second metal oxide layer, before the forming of the second electrode.

10. The method of claim 1, further comprising:
forming a third metal oxide layer for supplying oxygen vacancy to the second metal oxide layer, over the second metal oxide layer, before the forming of the second electrode.

11. The method of claim 1, wherein the forming of the second metal oxide layer comprises replacing oxygen of the part of the first metal oxide layer with oxygen vacancy.

12. A method for fabricating a variable resistance memory device, comprising:
alternately stacking a plurality of first material layers and a plurality of interlayer dielectric layers, over a substrate;
forming a hole which exposes sidewalls of the plurality of first material layers by selectively etching the alternately stacked structure;
forming a first metal oxide layer which satisfies chemical stoichiometry, in the hole;
forming a second metal oxide layer which is lower in oxygen content than the first metal oxide layer by reducing a part of the first metal oxide layer; and
forming a second electrode in the hole in which the second metal oxide layer is formed.

13. The method of claim 12, wherein the forming of the first metal oxide layer is performed through an atomic layer deposition (ALD) or a chemical vapor deposition (CVD).

14. The method of claim 12, wherein the forming of the second metal oxide layer is performed using plasma processing under an atmosphere of a reduction gas.

15. The method of claim 12, wherein the first metal oxide layer includes Ta₂O₅, and the second metal oxide layer includes TaOx, x being less than 2.5.

16. The method of claim 12, wherein the second metal oxide layer has a thickness larger than the first metal oxide layer.

17. The method of claim 14, wherein relative thicknesses of the first metal oxide layer and the second metal oxide layer are controlled by adjusting a time of the plasma processing.

18. The method of claim 12, further comprising:
forming a second material layer having an energy band gap larger than the first metal oxide layer, in the hole, before the forming of the first metal oxide layer.

19. The method of claim 12, further comprising:
forming a second material layer having an energy band gap larger than the first metal oxide layer, on the second metal oxide layer, before the forming of the second electrode.

20. The method of claim 12, further comprising:
forming a third metal oxide layer for supplying oxygen vacancy to the second metal oxide layer, on the second metal oxide layer, before the forming of the second electrode.

21. The method of claim 12, wherein the first material layers comprise conductive layers.

22. The method of claim 12, further comprises:
replacing the first material layers with conductive layers, after the forming of the second electrode,
wherein the first material layers comprise sacrificial layers which have an etching selectivity with respect to the interlayer dielectric layers.

23. The method of claim 12, wherein the forming of the second metal oxide layer comprises replacing oxygen of the part of the first metal oxide layer with oxygen vacancy.

24. A variable resistance memory device comprising:
a bottom electrode;
a variable resistance material layer including a first metal oxide layer and a second metal oxide layer which are sequentially stacked over the bottom electrode, wherein the first metal oxide satisfies chemical stoichiometry, and the second metal oxide layer is lower in oxygen content than the first metal oxide layer while having the same material as the first metal oxide layer; and
a top electrode formed over the variable resistance material layer.

25. The variable resistance memory device of claim 24, the first metal oxide layer includes a Ta₂O₅ layer and the second metal oxide layer includes a TaOx layer, x being less than 2.5.

26. The variable resistance memory device of claim 24, further comprising:
a material layer interposed between the bottom electrode and the variable resistance material layer or between the top electrode and the variable resistance material layer and having an energy band gap larger than the first metal oxide layer.

27. The variable resistance memory device of claim 24, further comprising:
a third metal oxide layer interposed between the top electrode and the variable resistance material layer and configured to supply oxygen vacancy to the second metal oxide layer.

28. The variable resistance memory device of claim 24, wherein the second metal oxide layer has a thickness larger than the first metal oxide layer.

29. The variable resistance memory device of claim 24, wherein the second metal oxide layer includes more oxygen vacancy than the first metal oxide layer.
